(19) United States
(12) Patent Application Publication
(10) Pub. No.: US 2025/0283245 A1
(43) Pub. Date: Sep. 11, 2025

(54) TRANSPARENT HORIZONTAL GRADIENT FREEZE APPARATUS WITH REGULATED GROWTH RATE

(71) Applicant: BAE SYSTEMS Information and Electronic Systems Integration Inc., Nashua, NH (US)

(72) Inventors: Jani Jesenovec, Merrimack, NH (US); Kevin T. Zawilski, Arlington, MA (US); Peter G. Schunemann, Hollis, NH (US)

(73) Assignee: BAE SYSTEMS Information and Electronic Systems Integration Inc., Nashua, NH (US)

(21) Appl. No.: 18/600,906

(22) Filed: Mar. 11, 2024

(51) Int. Cl. C30B 13/28; C30B 13/10; C30B 13/14; C30B 13/16; C30B 29/40

(52) U.S. Cl. CPC C30B 13/28; C30B 13/10; C30B 13/14; C30B 13/16; C30B 29/40

(57) ABSTRACT

A transparent horizontal gradient freeze (HGF) furnace enables determining a crystallizing growth rate of an ingot by optically monitoring the rate at which a solid/liquid interface traverses across a charge of melted precursor material. The crystallization can be recorded for subsequent analysis, or a machine vision system can monitor and report the solid/liquid traversing rate in near real time, thereby enabling automated regulation of the growth rate to ensure uniform growth. Embodiments implement the disclosed furnace to produce crystalline or polycrystalline indium antimonide mixed with 1.8 wt % nickel antimonide (InSb:NiSb) at a growth rate specified according to required InSb:NiSb properties and a predetermined relationship between the growth rate and the properties of the NiSb needles formed in the ingot. Growth rates can be between 0.02 and 0.08 cm/hr for substantially single crystal ingots, and between 0.5 and 1.5 cm/hr for polycrystalline ingots. The InSb:NiSb can be doped with tellurium.

### FIELD

The disclosure relates to apparatus and methods of growing crystalized materials, and more particularly to horizontal gradient freeze furnaces and to methods of growing crystallized Indium Antimonide (InSb) semiconductor materials.

### BACKGROUND

Well established methods of producing single crystal and polycrystalline semiconductors and other crystalized materials include Czochralski (CZ), Vertical Bridgman (VB), Horizontal Bridgman (HB) and Travelling Heater Method (THM). A less common method is Horizontal Gradient Freeze (HGF).

When it is desirable to carefully regulate the growth rate of a crystallized material, a vertical growth method is typically employed, such as CZ, VB, or THM, because these methods enable the growth rate of the “boule” of crystalized material to be actively regulated by monitoring the weight of the boule as it is grown and pulled out of the melt, and adjusting the growth parameters accordingly.

However, vertical growth methods are not always economically viable when only relatively small quantities of crystalized material are needed. For example, at one time a eutectic alloy of Indium Antimonide (InSb) mixed with 1.8 wt % Nickel Antimonide (NiSb), referred to herein as InSb:NiSb. was widely used in a variety of electro-optical applications, including infrared windows, Hall sensors, and magneto-resistor devices. During the past few decades, however, the demand for InSb:NiSb has substantially decreased, as many of these requirements have been met by other materials and devices. Nevertheless, single crystal and polycrystalline InSb:NiSb has remained critically important for certain specialized applications, such as for magneto-resistor devices used in some implementations of “fly-by-wire” aeronautics.

In the past, InSb:NiSb was produced in relatively large quantities using methods such as Czochralski (CZ), Vertical Bridgman (VB), Horizontal Bridgman (HB) and Travelling Heater Method (THM). However, these traditional methods have ceased to be economically viable as the demand for InSb:NiSb has diminished, with the result that commercial manufacture of the material has ceased, and existing applications currently rely on an existing inventory of InSb:NiSb that was produced about 30 to 40 years ago, which is nearly depleted.

What is needed, therefore, is an apparatus and method of producing crystallized materials, such as polycrystalline InSb:NiSb, that provides an actively regulated growth rate and is economically viable for growing smaller quantities of crystallized material.

### SUMMARY

The present disclosure is an apparatus and method of producing crystallized materials, such as polycrystalline InSb:NiSb, that provides an actively regulated growth rate and is economically viable for growing smaller quantities of crystallized material.

One general aspect of the present disclosure is a horizontal crystal growing system that includes a controller and a horizontal growth furnace (HGF furnace) comprising an insulating wall surrounding an interior of the HGF furnace and extending along a horizontal growth direction thereof. The HGF further includes a plurality of temperature measurement devices in data communication with the controller and configured to measure temperatures at a plurality of locations within the interior of the HGF furnace, and a plurality of heating elements within the interior of the HGF furnace, the heating elements being configured to control both an average temperature and a temperature gradient in the horizontal growth direction when energized by the controller. The horizontal crystal growing system further includes an optical system external to the HGF furnace that is configured to optically monitor melted precursor material through an observation section of the insulating wall as the precursor material crystallizes in a crystal growing region of a crystal growth boat that is located within the interior of the HGF furnace and aligned with the horizontal growth direction.

Another general aspect of the present disclosure is a method of growing an ingot of crystallized Indium Antimonide (InSb) mixed with 1.8 wt % Nickel Antimonide (NiSb), referred to herein as InSb:NiSb. The method includes determining a required average length and density of NiSb needles to be formed in the InSb:NiSb during crystallization thereof, determining a required InSb:NiSb growth rate that will provide crystallized InSb:NiSb having the required average length and density of NiSb needles formed therein, placing InSb:NiSb precursor material into a crystal growing region of a crystal growth boat, placing the crystal growth boat into an interior of a horizontal gradient freeze furnace (HGF furnace), the crystal growth boat being oriented in a horizontal growth direction of the HGF furnace, increasing an average temperature in the interior of the HGF furnace above a melting point of the precursor material, establishing a crystalizing temperature gradient in the interior of the HGF furnace extending in the horizontal growth direction, and reducing the average temperature within the interior of the HGF furnace at a temperature reduction rate that causes the melted precursor material to crystalize at an actual growth rate that is substantially equal to the required growth rate, thereby forming the ingot of crystallized InSb:NiSb. During said crystalization of the melted precursor, a solid/liquid interface that divides crystalized InSb:NiSb from melted precursor material within the crystal growing region traverses horizontally across the crystal growing region in the horizontal growth direction of the HGF furnace at a traversing rate that corresponds to the actual growth rate.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1A is a cross-sectional side view of an HGF furnace according to embodiments of the present disclosure;

FIG. 1B is a top view of the HGF furnace of FIG. 1A;

FIG. 2A is a flow diagram that illustrates HGF crystallization in an embodiment of the present disclosure;

FIG. 2B is a top view of an HGF furnace similar to FIG. 1B but including a video camera system that enables HGF crystallization to be recorded for subsequent determination of the HGF growth rate;

FIG. 2C is a top view of an HGF furnace similar to FIG. 1B but including a machine vision system that is configured to monitor and determine the growth rate of HGF crystallization in near real time, enabling the growth rate to be regulated and stabilized;

FIG. 3A is a graph that compares programmed and actual growth rates in an embodiment applied to growing a single crystal ingot of InSb:NiSb;

FIG. 3B is a graph that compares programmed and actual growth rates in an embodiment applied to growing a polycrystalline ingot of InSb:NiSb;

FIG. 4 is a graph that illustrates relationships between average needle density and average needle length as a function of growth rate of the crystallized material according to embodiments of the present disclosure;

FIG. 5 is a flow diagram that illustrates applying the apparatus of FIG. 2C to the HGF manufacture of InSb:NiSb, according to an embodiment of the present disclosure; and

FIG. 6 is a graph that compares normalized magnetoresistance as a function of temperature for undoped InSb:NiSb and for InSb:NiSb doped with Tellurium.

### DETAILED DESCRIPTION

The present disclosure is an apparatus and method of producing crystallized materials, such as polycrystalline InSb:NiSb, that provides an actively regulated growth rate and is economically viable for growing smaller quantities of crystallized material.

The disclosed apparatus is a “horizontal gradient freeze” (HGF) furnace. The disclosed HGF is referred to herein as a “transparent” HGF because its outer wall includes an “observation section” that is sufficiently transparent to enable optical observation and analysis of a melted precursor material within the HGF furnace as it crystallizes, whereby the growth rate of the resulting crystallized material can be determined. In embodiments, heating elements of the HGF provide sufficient optical illumination during said crystallization to enable the optical observation thereof through the observation section.

Embodiments include a video system that is configured to record the crystallization process for subsequent analysis. Various embodiments include a machine vision system that is able to automatically determine the growth rate in near real time, thereby enabling a controller to regulate the growth rate as the material crystallizes.

Embodiments of the disclosed method apply the HGF furnace to the production of single crystal and/or polycrystalline InSb:NiSb at a growth rate that is specified according to device requirements for the InSb:NiSb and a relationship between growth rates and resulting InSb:NiSb properties that has been predetermined established by experimentation.

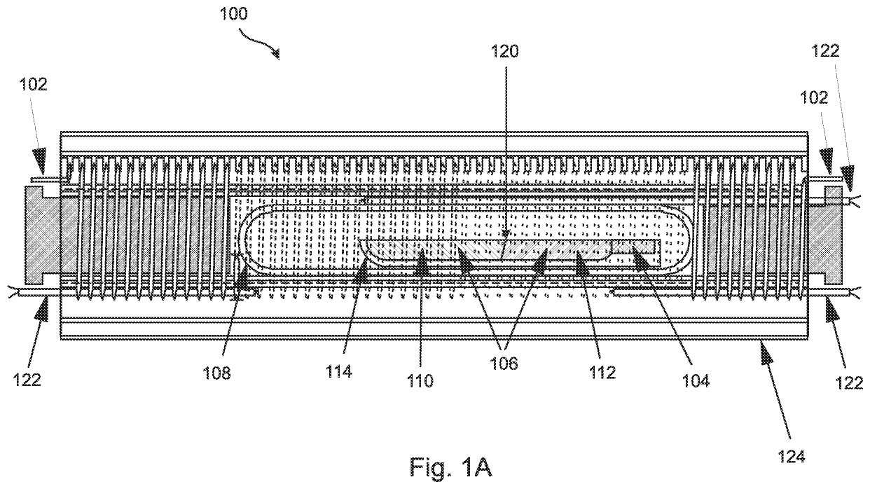

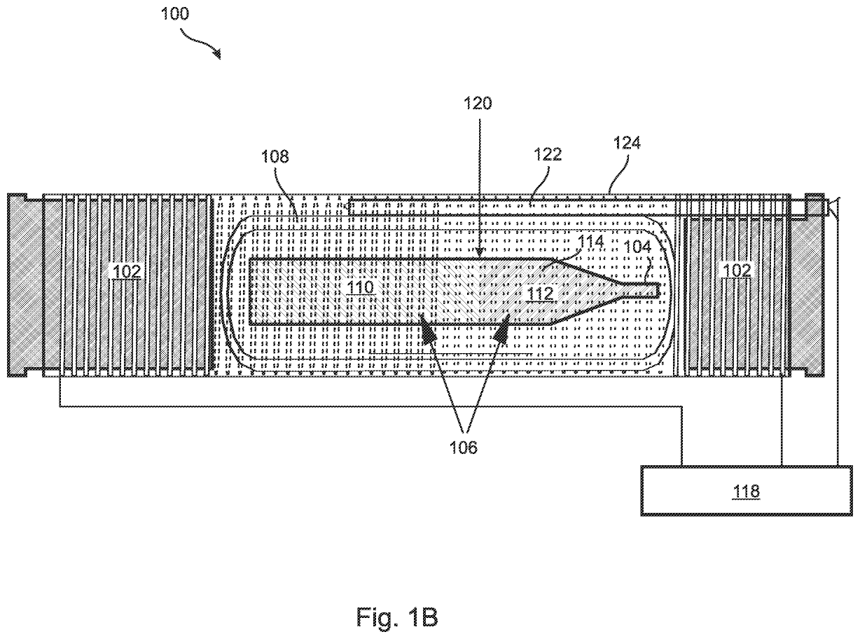

With reference to the side view of FIG. 1A and the top view of FIG. 1B, in embodiments of the present disclosure the HGF furnace 100 features two or more heating elements 102 that create two corresponding heating zones, namely a “hot” zone on the left, and a “cold” zone on the right. The heating elements 102 are configured essentially as heating “coils” that are located within an insulating wall 124 of the HGF 100 and surround an interior region of the HGF 100, and that extend along substantially the entire length of the HGF 100, with one of the coils 102 surrounding the hot zone and the other surrounding the cold zone. Dashed lines are used in the figures to illustrate the heating elements 102 in the central region of the furnace 100 so that the internal components of the furnace 100 to be more easily observed behind the dashed lines. In embodiments, the “pitch” of the heating coils 102, i.e. the spacing between windings of the coils 102, is varied across their lengths in a manner that improves the linearity of temperature gradients created by the coils 102.

A “boat” 114, such as a pyrolytic boron nitride (PBN) boat 114 or a vitreous carbon boat 114, includes a crystal growing region 106, and in embodiments also a seed well 104 at the cold end of the boat 114 that is configured to contain a seed crystal in fluid communication with the crystal growing region 106 of the boat 114.

Also illustrated in FIG. 1B is a controller 118 that is in electrical communication with the heating elements 102 and with temperature sensors 122, such as thermocouples, that extend within the HGF furnace 100, the controller 118 being thereby able to measure and to regulate the internal temperature at a plurality of locations within the HGF furnace 100.

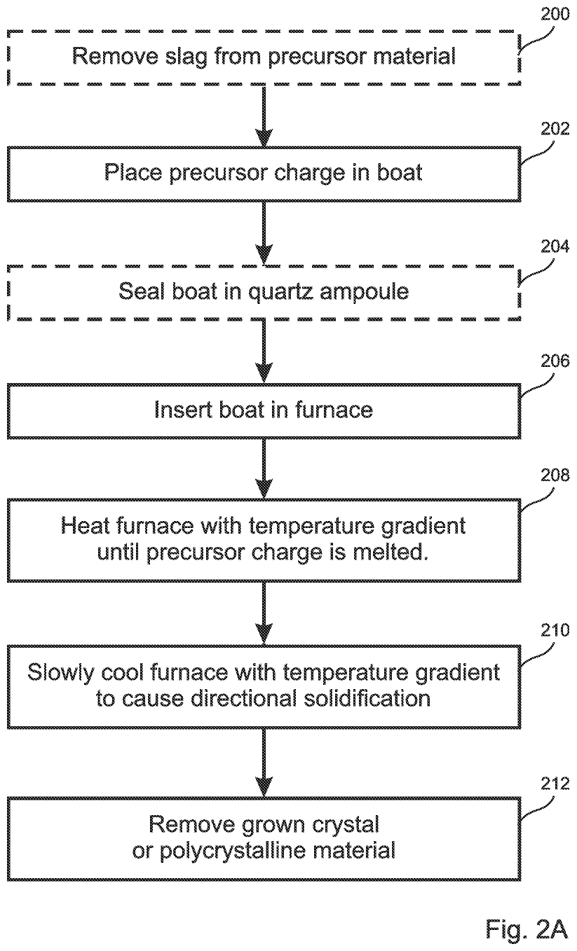

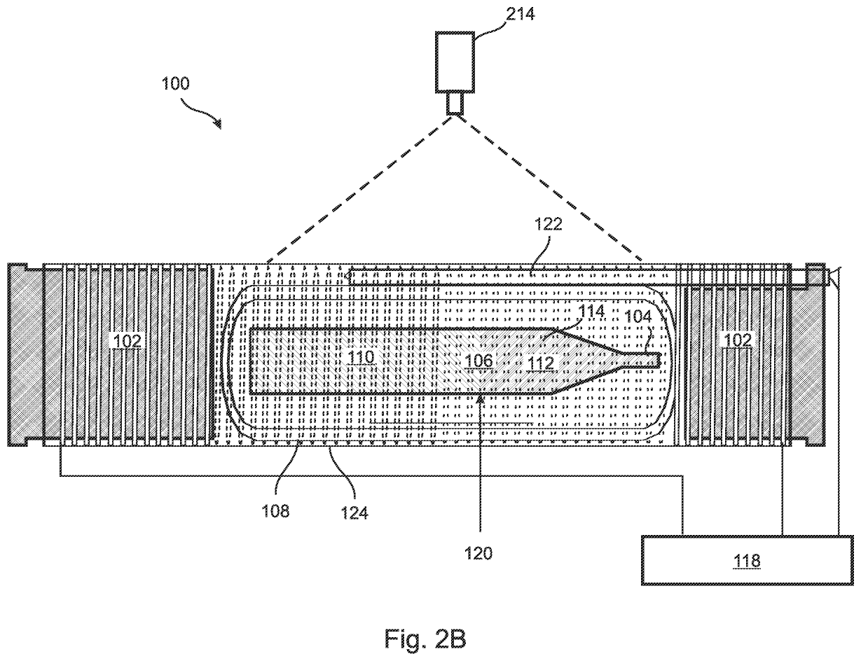

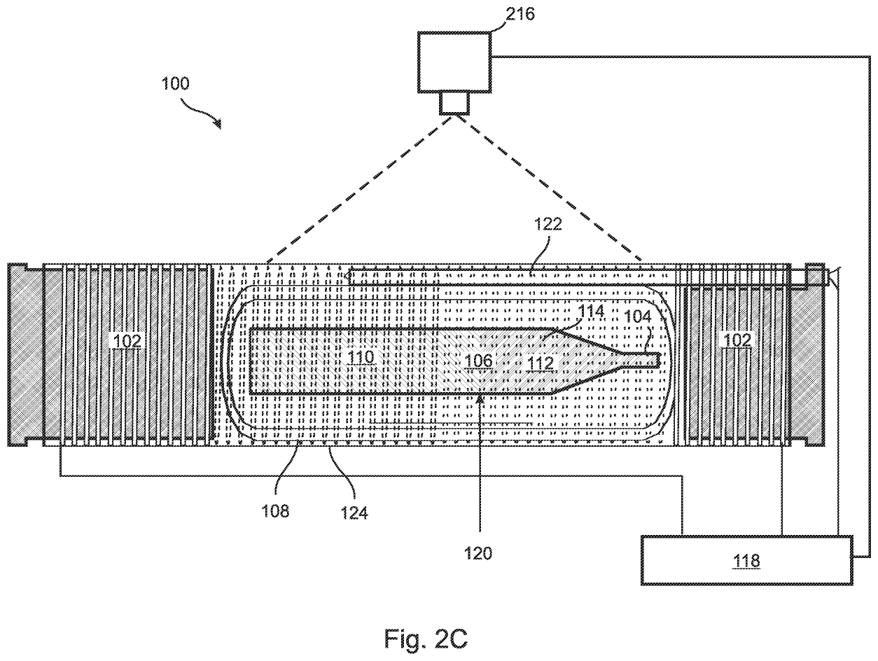

With reference to FIG. 2A, growing crystallized materials according to the disclosed method includes placing 202 a “charge” of precursor material 110, such as a mixture of indium metal, antimony metal, NiSb, and tellurium metal in the required proportions, in the crystal growing region 106 of the boat 114. If a single crystal is being grown, the method further includes placing a seed crystal, for example a crystal of InSb:NiSb, in the seed well 104 of the boat 114. The boat is then inserted 206 into the HGF furnace 100. In embodiments, the boat 114 is first encapsulated and sealed 204 within an evacuated or inert gas filled ampoule 108, such as a quartz ampule 108, and then the ampoule is inserted 206 into the furnace 100. In other embodiments, a controlled over-pressure of argon, or of another inert gas, is maintained over the boat 114 within the HGF furnace.

The average temperature within the furnace 100 is gradually raised 208 by the two heating elements 102 until the precursor charge 106 is fully melted. As used herein, the terms “melt” and “melted” refer to a state in which the molecules included in the precursor material 110 are separately mobile and homogeneously mixed together. If a single crystal is being grown, a shallow axial melting temperature gradient (typically 1.5-2.0° C./cm) is maintained across the boat 114 as it is being heated, such that that melting of the precursor charge 106 begins at the hot end of the boat (furthest from the seed well 104), while the seed crystal is preserved until the temperature has been raised to partially melt the seed crystal in the seed well 104 at the cold end of the boat 114.

The average temperature within the HGF furnace 100 is then gradually reduced 210 while a crystallizing temperature gradient (typically 1-3° C./cm) is maintained, during which crystallization of the melted precursor material 110 occurs by directional solidification. In embodiments, the reduction rate of the average temperature within the HGF is controlled such that crystallization of the melted precursor material 110 occurs at a rate of between 0.05 mm/h and 5 mm/h. Once the crystallized material 112 is fully solidified, the boat 114 is cooled to room temperature. The crystallized material 112 can then be removed 212 from the boat, cut and polished as needed.

The HGF furnace 100 enables precise control of the temperature gradients that are established within the furnace 100, thereby allowing the shape of the solid-liquid interface 120 between melted precursor material 110 and the solidified, crystalline or polycrystalline material 112 in the crystal growing region 106 of the boat 114 to be controlled, while vapor transport is minimized.

In embodiments, the disclosed method includes a step of reducing impurities by removing 200 contaminants or “slag,” such as oxidized precursor metals, from the precursor material before crystallization. In some of these embodiments, where the slag has a higher melting point than the precursors and tends to float to the surface of the melted precursor material 110, the method includes melting and then cooling the precursor material 110, and then physically removing the slag from the surface of the re-solidified precursor material 110. In similar embodiments, the melted precursor material 110 is poured out of the boat 114 into a separate storage container, leaving the slag behind in the boat 114, which can then be cleaned before the precursor material 110 is returned to the boat 114 and crystalized in the HGF furnace 100. In other embodiments, at least one of the metallic precursors, such as indium metal, is etched, for example using nitric acid, to remove surface oxides and any other surface contaminants before the metallic precursor is added to the boat 114. In various embodiments, the charge of precursor material 110 s further purified using a UV ozone etch at 100° C.

As the precursor material 110 in the crystal growing region 106 is melted and then crystallized within the furnace 100, embodiments further enable optical observation and monitoring of the melting process and crystallization by implementing a “transparent” HGF furnace 100 that enables the precursor material 110 to be viewed through an “observation section” of the insulating wall 124 of the HGF 100. In these embodiments, it is possible to directly view the traversing rate of the solid/liquid interface 120 as it moves across the crystal growing region 106.

For example, in the embodiment of FIGS. 1A and 1B, the insulating wall 124 of the furnace 100 is a transparent wall that is insulated by a gold-mirror coating. The entirety of the insulating wall 124 is the “observation section.” The gold coating is substantially opaque and reflective at infra-red and longer wavelengths, which significantly reduces infrared emissions from within the furnace 100, while being sufficiently transparent at visible wavelengths to enable the boat 114 to be optically observed and monitored during the crystallization process.

Due to the temperatures that are reached by the heating elements 102 during crystallization, a very bright “glow” is generated within the furnace 100, which is dimmed to a more manageable intensity by the gold-coated mirror, while remaining sufficient to enable observation of the crystalizing material within the furnace 100. In other embodiments, the observation section extends only over a portion of the insulating wall, while the remainder of the insulating wall is opaque.

With reference to FIG. 2B, embodiments include an optical system 214 that is capable of optically recording the changes in the crystal growing region 106 during a crystallization “cycle” of melting the precursor material 110 and directionally solidifying the crystalized product 112. The recorded information can then subsequently be analyzed to determine the growth rate of the crystallized material as a function of time during the crystallization process. If the growth rate is not equal to a desired growth rate, the cooling rate can be adjusted accordingly for subsequent crystallization cycles. If the growth rate is not constant during the crystallization process, a “cooling function” can be implemented that varies the rate of temperature reduction in a compensatory manner.

With reference to FIG. 2C, various embodiments include a machine vision system 216 that is configured to monitor the crystal growing region 106 and to automatically detect the solid/liquid interface 120 and its traversing rate. In embodiments, the machine vision system 216 applies artificial intelligence (AI) to identify the solid/liquid interface 120 and determine its traversing rate. For example, the AI of the machine vision system 216 can be trained by recording a plurality of crystal growing session and supplying the recordings to the AI of the machine vision system 216 together with their manually determined transition rates.

Based, at least in part, on the monitored traversing rate, the controller 118 in some of these embodiments is able to adjust the temperature gradient and/or the reduction rate of the average temperature within the furnace 100 substantially in real time as the crystallized material is formed, thereby providing a regulated, constant growth rate throughout the crystallization process, and an improved uniformity of the crystallized material 112.

Embodiments of the present disclosure apply HGF crystal growth to the production of InSb:NiSb. Among other requirements, economic production of InSb:NiSb depends upon implementing a method that results in a high yield of device-grade material. In general, the yield of a crystallizing process will depend on several factors, including the presence of impurities, interaction of the material with crucible walls, and mechanical vibrations present during crystallization, as well as the maintaining of a constant, desired rate of crystallization.

Unlike the methods that were historically used to produce InSb:NiSb, such as Czochralski (CZ), Vertical Bridgman (VB), Horizontal Bridgman (HB) and Travelling Heater Method (THM), HGF does not require mechanical movement of any element of the reactor during crystallization. Instead, only the electronically generated thermal gradient and average internal temperature of the furnace are varied as the material solidifies. The present method thereby eliminates defects that might otherwise be caused by mechanical vibrations as the precursor material is crystallized.

In embodiments, impurities are removed from the InSb:NiSb precursor material as described above with reference to FIG. 2A.

Interaction of the precursor material with the walls of the boat 114 is minimized by growing slabs of InSb:NiSb that are slightly larger then what is needed, and then removing material from the surfaces of the resulting slab In embodiments, the slabs are at least 15 cm in length, at least 3 cm in width, and at least 3 mm in thickness.

In various embodiments, “single crystal” ingots of InSb:NiSb, defined herein as ingots comprising at least one single crystal of InSb:NiSb that represents at least 30% of the total volume of the ingot, are produced using growth rates of between 0.02 cm/h and 0.08 cm/h, while polycrystalline InSb:NiSb ingots composed of smaller crystals, none of which exceeds 5% of the total volume of the ingot, is produced using growth rates between 0.05 cm/h and 1.5 cm/h, depending on the NiSb needle morphology that is required.

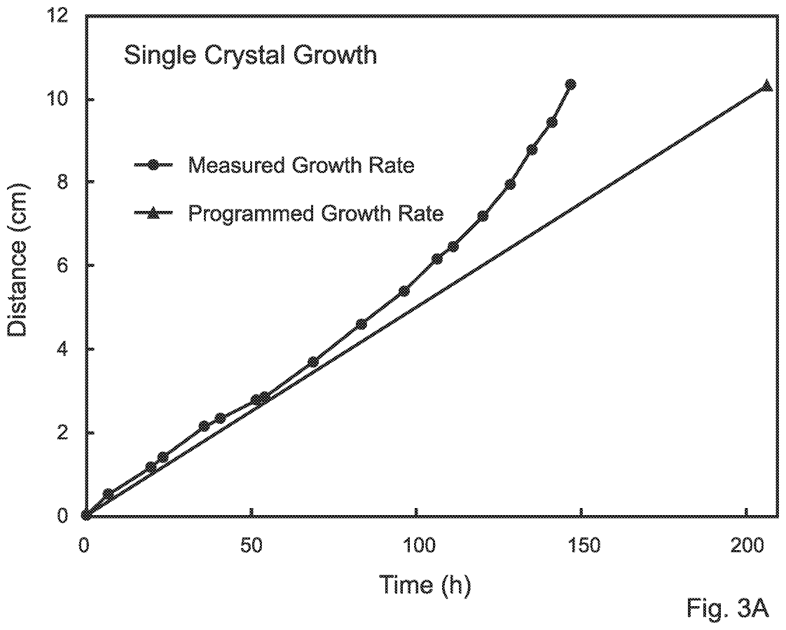

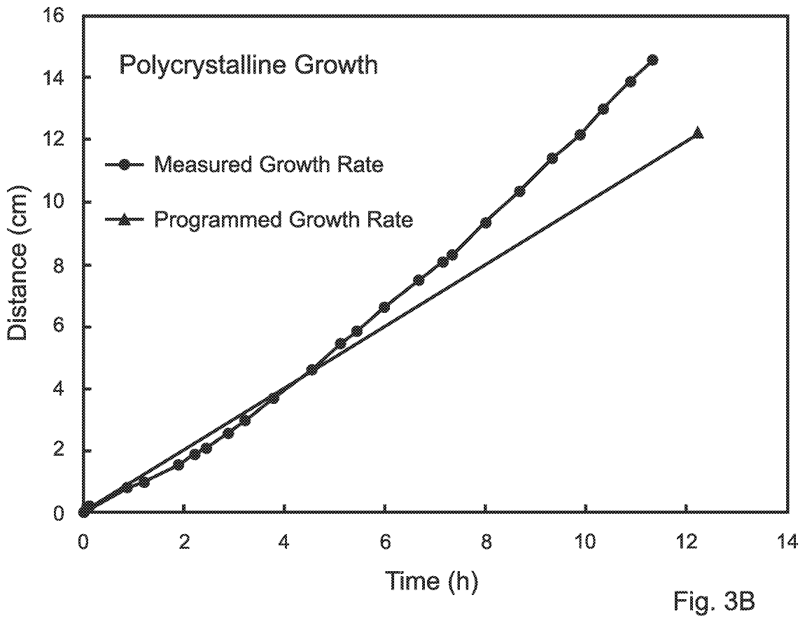

For example, the growth rates for the data presented in FIGS. 3A and 3B were approximately 0.05 cm/h for single crystal growth (FIG. 3A), and approximately 1.0 cm/h for polycrystalline growth (FIG. 3B). As can be seen in FIGS. 3A and 3B, the actual crystal growth rate can diverge from the expected, “programmed” rate as the growth process continues. When the growth rate is programmed to be constant, it generally tends to increase during the process.

During the crystallization of InSb:NiSb, NiSb needles (hexagonal wurtzite structure) form in the InSb (zincblende F43 m structure) matrix in the growth direction of the crystallized material 112, due to a quasi-binary eutectic phase diagram. The quality and suitability of the resulting material for implementation in a given device depends critically upon the density, size, and uniformity of orientation of these NiSb needles, which in some cases must be matched to the physical dimensions of the device. For magneto-resistive devices, the variability of the resistance as a function of the applied magnetic field tends to be greater for materials with shorter average needle lengths and higher average needle densities.

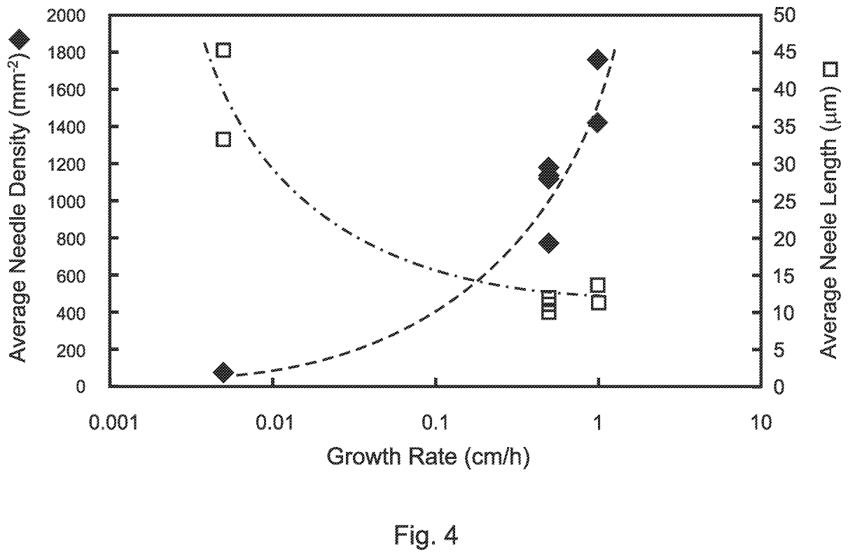

Embodiments of the present invention were enabled, at least in part, by a realization that, in the substantial absence of impurities and other contrary factors, the lengths and density of these “needles” is governed mainly by the growth rate of the crystallization process, which is substantially proportional to the traversing rate at which the solid/liquid interface 120 that is formed between the melted precursor material 110 and the crystallized InSb:NiSb 112 moves across the crystal growing region 106 as the ingot is formed. For example, it is evident from the data presented in FIG. 4 that the density and lengths of the NiSb needles within InSb:NiSb is strongly dependent on the growth rate.

Accordingly, by controlling the growth rate of the ingot as it is formed, the average lengths and the density of the needles can be “tuned” to match the requirements of a specific device application. In particular, it is evident from FIG. 4 that very careful and accurate control of the growth rate between approximately 0.5 cm/h and 1.0 cm/hr is required to “tune” the average needle density in polycrystalline InSb:NiSb between about 800 per mm² and about 1800 mm², with lower average needle densities and longer average needle lengths being obtained at slower growth rates.

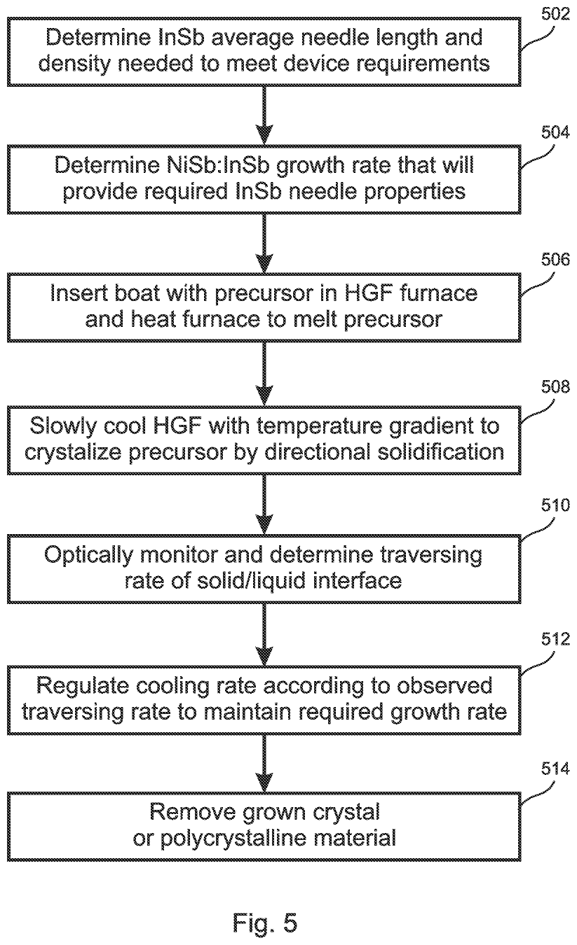

The disclosed method of applying that apparatus of FIG. 2C to the HGF manufacture of InSb:NiSb is summarized in the flow diagram of FIG. 5. In embodiments, the process begins with determining 502 the density and average lengths of the NiSb needles that will be required to optimize the properties of the HGF-grown InSb:NiSb for a given device application. A “required” growth rate is then determined 504 that will result in crystallized InSb:NiSb having the required NiSb needle properties, according to established relationships between the InSb:NiSb crystallization rate and the resulting lengths and density of the NiSb needles, based on previously measured data such as are presented in FIG. 4. The InSb:NiSb precursor is then placed in the transparent HGF furnace and melted 506, a temperature gradient is established, and the precursor is slowly cooled 508, resulting in directional crystallization of the InSb:NiSb.

The traversing of the solid/liquid interface 120 across the crystal growing region 106 is optically monitored 510 during the crystallization process. In some of these embodiments, optical observations of the traversing rate are recorded and subsequently analyzed, for example by means of the video recording system 214 of FIG. 2B, and the results are then used to adjust the cooling rate for future crystallization cycles.

In the embodiment of FIG. 5, the traversing rate is automatically determined in near real time from optical observations made by the machine vision system 216 of FIG. 2C, and used to adjust the temperature reduction rate as the crystallization process progresses, thereby actively regulating the crystallization growth rate in near real time, so that it remains “substantially” equal to the required growth rate during the entire InSb:NiSb crystallization process 512. As a result, the density and the average length of the NiSb needles are consistent and equal to their required levels throughout the resulting ingot of InSb:NiSb. The ingot of InSb:NiSb is then removed 514 from the HGF furnace and used to form the desired devices. It will be understood that, recognizing the inherent limitations associated with maintaining an exact growth rate, the term “substantially equal” is used herein to refer to the desired growth rate plus or minus deviations associated with optical measurement tolerances and observation latencies associated with a machine vision system 216, as well as delays between adjustments of the current applied to the heating elements 102 and actual changes in the temperature within the HGF 100.

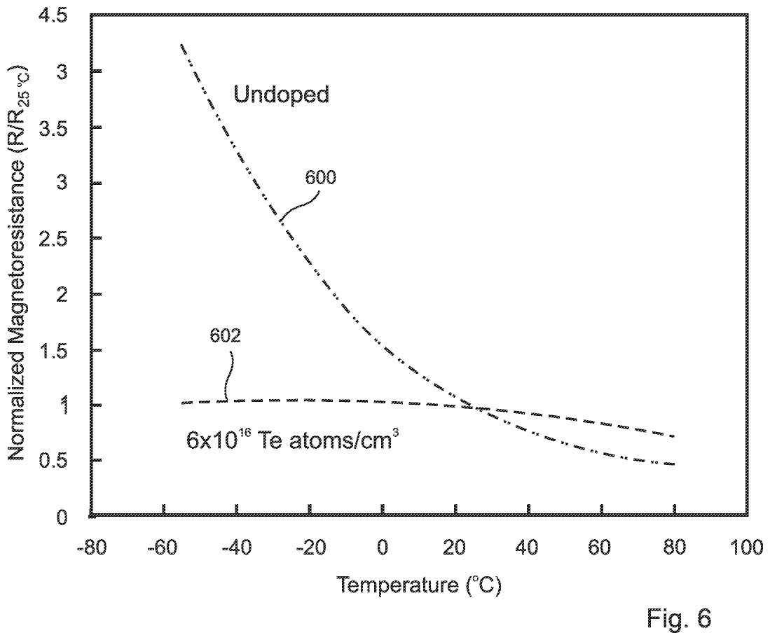

For many applications, the performance of the resulting InSb:NiSb devices tends to be highly temperature dependent without extrinsic doping, because the intrinsic carriers in the material tend to be frozen out at lower temperatures. Accordingly, in embodiments the InSb:NiSb includes one or more extrinsic carrier dopants. In various embodiments, the dopants include one or more of Si, Sn, and Te. For example, in some embodiments the InSb:NiSb is doped with between 4×10¹⁶ Te atoms per cm³ and 8×10¹⁶ Te atoms per cm³. An example is presented in FIG. 6, which compares temperature dependent changes in magnetoresistance for devices having substantially the same device geometry that are made from undoped InSb:NiSb 600 and from InSb:NiSb 602 that has been doped with 6×10¹⁶ Te atoms per cm³. It can be seen in the figure that doping the material with an extrinsic carrier dopant greatly reduces the dependence of the magnetoresistance on temperature, at the cost of a modest reduction in the magnetoresistance at most temperatures.

The foregoing description of the embodiments of the disclosure has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the disclosure to the precise form disclosed. Many modifications and variations are possible in light of this disclosure.

Although the present application is shown in a limited number of forms, the scope of the disclosure is not limited to just these forms, but is amenable to various changes and modifications. The present application does not explicitly recite all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

What is claimed is:

1. A horizontal crystal growing system comprising:
a controller;
a horizontal growth furnace (HGF furnace) comprising:
an insulating wall surrounding an interior of the HGF furnace and extending along a horizontal growth direction thereof;
a plurality of temperature measurement devices in data communication with the controller and configured to measure temperatures at a plurality of locations within the interior of the HGF furnace; and
a plurality of heating elements within the interior of the HGF furnace, the heating elements being configured to control both an average temperature and a temperature gradient in the horizontal growth direction when energized by the controller; and
an optical system external to the HGF furnace and configured to optically monitor melted precursor material through an observation section of the insulating wall as the precursor material crystallizes in a crystal growing region of a crystal growth boat that is located within the interior of the HGF furnace and aligned with the horizontal growth direction.

2. The horizontal crystal growing system of claim 1, wherein the controller is configured to:
receive the measured temperatures from the temperature measurement devices
cause the heating elements to establish an average temperature within the interior of the HGF furnace that will cause a precursor material located within the crystal growing region of the crystal growth boat to melt;
establish a crystalizing temperature gradient extending in the horizontal growth direction within the interior of the HGF furnace; and
reduce the average temperature within the interior of the HGF furnace at a predetermined temperature reduction rate that causes the melted precursor material to crystalize;
said crystalizing of the melted precursor material being characterized by a horizontal traversing of a solid/liquid interface across the crystal growing region in the horizontal growth direction, wherein the solid/liquid interface divides crystalized material from melted precursor material within the crystal growing region, said traversing of the solid/liquid interface being at a traversing rate that corresponds to an actual growth rate of the crystalized material.

3. The horizontal crystal growing system of claim 2, wherein the optical system comprises an optical recorder configured to create a recording of the crystalizing of the melted precursor.

4. The horizontal crystal growing system of claim 2, wherein the optical system is a machine vision system that is configured to determine the traversing rate of the solids/liquids interface in near real time as the melted precursor is crystalized.

5. The horizontal crystal growing system of claim 4, wherein the controller is configured to adjust and regulate the temperature reduction rate in near real time as the melted precursor is crystalized according to the determined traversing rate.

6. The horizontal crystal growing system of claim 1, wherein the insulating wall comprises a gold coating applied to at least one of an inner and an outer surface thereof, said gold coating being reflective at infra-red and longer wavelengths, while being translucent at optical wavelengths.

7. A method of growing an ingot of crystallized Indium Antimonide (InSb) mixed with 1.8 wt % Nickel Antimonide (NiSb), referred to herein as InSb:NiSb, the method comprising:
determining a required average length and density of NiSb needles to be formed in the InSb:NiSb during crystallization thereof;
determining a required InSb:NiSb growth rate that will provide crystallized InSb:NiSb having the required average length and density of NiSb needles formed therein;
placing InSb:NiSb precursor material into a crystal growing region of a crystal growth boat;
placing the crystal growth boat into an interior of a horizontal gradient freeze furnace (HGF furnace), the crystal growth boat being oriented in a horizontal growth direction of the HGF furnace;
increasing an average temperature in the interior of the HGF furnace above a melting point of the precursor material;
establishing a crystalizing temperature gradient in the interior of the HGF furnace extending in the horizontal growth direction; and
reducing the average temperature within the interior of the HGF furnace at a temperature reduction rate that causes the melted precursor material to crystalize at an actual growth rate that is substantially equal to the required growth rate, thereby forming the ingot of crystallized InSb:NiSb;
wherein during said crystalization of the melted precursor, a solid/liquid interface that divides crystalized InSb:NiSb from melted precursor material within the crystal growing region traverses horizontally across the crystal growing region in the horizontal growth direction of the HGF furnace at a traversing rate that corresponds to the actual growth rate.

8. The method of claim 7, wherein the crystalizing gradient is between 1° C./cm and 3° C./cm.

9. The method of claim 7, wherein the ingot of crystalized InSb:NiSb comprises at least one single crystal of InSb:NiSb that occupies at least 30% of a total volume of the ingot.

10. The method of claim 9, wherein the crystal growth boat further comprises a seed well, and wherein the method further comprises placing a seed crystal of InSb:NiSb in the seed well before placing the crystal growth boat into the interior of the HGF furnace.

11. The method of claim 10, wherein increasing the average temperature within the HGF furnace above the melting point of the precursor material comprises establishing a melting gradient extending in the horizontal growth direction within the interior of the HGF furnace, and increasing the average temperature within the interior of the HGF furnace until the precursor material is fully melted and the seed crystal is partially melted.

12. The method of claim 11, wherein the melting gradient is between 1.5° C./cm and 2.0° C./cm.

13. The method of claim 9, wherein the required growth rate is between 0.02 cm/h and 0.08 cm/h.

14. The method of claim 7, wherein the ingot of crystalized InSb:NiSb is a polycrystalline ingot comprising a plurality of crystals of InSb:NiSb, none of which occupies more than 5% of a total volume of the ingot.

15. The method of claim 14, wherein the required growth rate is between 0.5 cm/h and 1.5 cm/h.

16. The method of claim 14, wherein the HGF furnace is a transparent HGF furnace having an outer wall that includes an observation section, said observation section being sufficiently transparent to enable optical observation of the solid/liquid interface as it traverses horizontally across the crystal growing region.

17. The method of claim 16, further comprising, as the InSb:NiSb ingot is crystallizing:
monitoring by an optical system of the traversing rate of the solid/liquid interface as it traverses horizontally across the crystal growing region; and
determining from the monitored traversing rate an actual growth rate of the InSb:NiSb ingot.

18. The method of claim 17, further comprising, as the InSb:NiSb is crystallizing:
determining in near real time from the monitored traversing rate an actual growth rate of the InSb:NiSb ingot; and
periodically or continuously making automatic adjustments of the temperature reduction rate, thereby automatically regulating the actual InSb:NiSb growth rate to remain equal to the required InSb:NiSb growth rate during the crystallizing of the melted precursor material.

19. The method of claim 7, further comprising doping the InSb:NiSb with at least one of tellurium, silicon, or tin.

20. The method of claim 7, further comprising doping the InSb:NiSb with between 4×10¹⁶ Te atoms per cm³ and 8×10¹⁶ Te atoms per cm³.
